(19) United States
(12) Patent Application Publication
(10) Pub. No.: US 2008/0185740 A1
(43) Pub. Date: Aug. 7, 2008

(54) Semiconductor and Method For Producing the Same

(75) Inventors: Xaver Schloegel, Sachsenkam (DE); Ralf Otremba, Kaufbeuren (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Muenchen (DE)

(21) Appl. No.: 11/572,358

(22) PCT Filed: Jul. 18, 2005
(86) PCT No.: PCT/DE2005/001262

§ 371 Date: Mar. 24, 2008

(30) Foreign Application Priority Data
Jul. 19, 2004 (DE) 10 2004 034 821.9

(51) Int. Cl. H01L 23/49; H01L 21/44

(52) U.S. Cl. 257/784; 438/612; 257/E23.024; 257/E21.476

(57) ABSTRACT

A semiconductor module and a method for producing the same is disclosed. One embodiment provides that an intermediate element has been or is formed, which has been or is formed for making electrical contact materially between a contact region provided and a connection region provided and in direct material and electrical contact with and for area adaptation between these.

The present invention relates to a semiconductor module and to a method for producing the same, in particular a semiconductor module in which a wedge has been or is provided as a buffer element.

On account of the ever rising integration density and miniaturization of semiconductor modules, corresponding connection regions for externally making contact with the modules are also being miniaturized to an ever greater extent. This is disadvantageous, however, insofar as corresponding connection elements, e.g. in the form of wires, cannot readily be scaled down with regard to their cross-sectional area, or insofar as making contact between a given connection element or wire and a given connection area would entail rising defect rates in the case of ever greater miniaturization in the context of an automatic production process.

Therefore, the invention is based on the object of specifying a semiconductor module and a method for producing the same in which contact can be made with the semiconductor module externally even in the case of rising miniaturization, that is to say shrinking of the connection areas, particularly simply and reliably.

The object on which the invention is based is achieved in the case of a semiconductor module with the features of claim 1. Furthermore, the object is achieved in the case of a method for producing a semiconductor module with the features of claim 6. The dependent subclaims respectively relate to advantageous developments of the semiconductor module according to the invention and of the method according to the invention for producing a semiconductor module.

The semiconductor module according to the invention is formed comprising a semiconductor region or chip having a semiconductor element arrangement and having a surface region, comprising at least one contact region or pad which is formed on the surface region of the semiconductor region or chip, for externally making electrical contact with the semiconductor element arrangement, comprising a connection element and a first end, which is formed in electrical contact with the contact region or pad, and comprising an intermediate element, which is formed for making electrical contact materially between the contact region or pad and the connection element and in direct material and electrical contact with and for area adaptation between these.

Consequently, according to the invention it is provided that, for externally making electrical contact, no direct contact is produced between a connection element and a contact region or pad of the semiconductor module, rather that an intermediate element is interposed materially in such a way that the intermediate element is present materially and electrically between the contact region or pad and the connection element, to be precise in a direct manner, and in this case also brings about an area adaptation between the contact region or pad, on the one hand, and the connection element, on the other hand. In this way it is conceivable for the contact regions or pads to be shrunk further, namely in the case of ever greater miniaturization and integration density, but for the connection elements, e.g. in the form of wires, to be able to remain essentially identical in terms of their dimensioning, because a corresponding area adaptation between the contact regions or pads, on the one hand, and the connection elements, on the other hand, is realized by means of the respectively interposed intermediate element, which can be shrunk further in the context of miniaturization.

The preferred embodiment of the semiconductor module according to the invention provides for the intermediate element to be formed as a wedge buffer element.

Another alternative or additional embodiment of the semiconductor module according to the invention provides for the at least one contact region or the at least one pad to be formed on a front side of the semiconductor module.

In addition or as an alternative to this, it is provided that a plurality of contact regions or pads are provided, and that each contact region or each pad is electrically connected to a respectively assigned connection element in each case via an assigned intermediate element.

Another advantageous development of the semiconductor module according to the invention provides for the connection element to be formed in each case as a bonding wire or as a wedge bonding wire.

In addition or as an alternative, it may be provided that the connection element is in each case formed from or with one or more materials from the group formed by aluminum, copper and gold.

It is further preferred for the first end of the intermediate element, said first end being in material contact with the contact region or pad, to be formed with a cross-sectional area which is less than or equal to the cross-sectional area of the contact region or pad.

It is furthermore preferably conceivable for the first end of the intermediate element, said first end being in material contact with the contact region or pad, to be formed with a cross section which approximately corresponds to that of the contact region or to that of the pad in terms of form and/or in terms of size.

Another preferred embodiment of the semiconductor module according to the invention provides for the connection element or the first end thereof to be formed with a cross section whose area is greater than the area of the contact region or pad.

Furthermore, it is conceivable for the second end of the intermediate element, said second end being in material and electrical contact with the connection element, to be formed with a cross section having an area which is greater than the area of the cross section of the first end of the intermediate element such that the area of the contact region or the pad is thereby adapted to the area of the cross section of the first end of the connection element.

A corresponding method for producing a semiconductor module is also provided in accordance with a further aspect of the present invention.

In the method according to the invention for producing a semiconductor module, a semiconductor region or chip having a surface region and having a semiconductor element arrangement is formed. Furthermore, at least one contact region or pad is formed which is formed on the surface region of the semiconductor region or chip and which serves for externally making electrical contact with the semiconductor element arrangement. Furthermore, a connection element is provided having a first end, which is formed in electrical contact with the contact region or pad. Furthermore, the invention provides an intermediate element, which is formed for making electrical contact materially between the contact region or pad and the connection element and in direct material and electrical contact with and for area adaptation between these.

In one advantageous development of the method according to the invention for producing a semiconductor module, the intermediate element is formed as a wedge buffer element.

Furthermore, as an alternative or in addition it may be provided that the at least one contact region or the at least one pad is formed on a front side of the semiconductor module.

In accordance with another alternative or additional embodiment of the method according to the invention for producing a semiconductor module, a plurality of contact regions or a plurality of pads are provided, each contact region or each pad being electrically connected to a respectively assigned connection element in each case via an assigned intermediate element.

In one particularly preferred embodiment of the method according to the invention for producing a semiconductor module, the connection element is formed in each case as a bonding wire or as a wedge bonding wire.

In addition or as an alternative it may be provided that the connection element is in each case formed from or with one or more materials from the group formed by aluminum, copper and gold.

Another preferred embodiment of the method according to the invention for producing a semiconductor module provides for the first end of the intermediate element, said first end being in material contact with the contact region or with the pad, to be formed with a cross-sectional area which is less than or equal to the cross-sectional area or the area of the contact region or the pad. As an alternative or in addition, in accordance with another preferred embodiment of the method according to the invention for producing a semiconductor module, it may be provided that the first end of the intermediate element, said first end being in material contact with the contact region or pad, is formed with a cross section which approximately corresponds to the contact region or the respective pad in terms of form and/or in terms of size.

In accordance with another alternative or additional embodiment of the method according to the invention for producing a semiconductor module it is provided that the connection element or the first end thereof is formed with a cross section whose area is greater than the area of the contact region or pad.

Another advantageous development of the method according to the invention for producing a semiconductor module provides for the second end of the intermediate element, said second end being in material and electrical contact with the connection element, to be formed with a cross section having an area which is greater than the area of the cross section of the first end of the intermediate element such that the area of the contact region or the pad is thereby adapted to the area of the cross section of the first end of the connection element.

These and further aspects of the present invention are also discussed further in the context of the explanations below:

It is proposed, in order to improve the electrical linking of small chips by means of aluminum wedge bonding wires, to apply a wedge buffer element on the chip front side and then to place a thick bonding wire for making contact with the chip front side on said wedge.

Nowadays the maximum bonding wire thickness for making contact with the chip front side is dependent on the size and design of the chip itself. Therefore, only thin bonding wires can be contact-connected directly on small chips, and, therefore, the electrical device performance for small chip or contact areas and thin bonding wires connected thereto is significantly impaired.

The use of a wedge buffer element enables the maximum bonding wire diameter to be contact-connected independently of the chip front side since the buffer element separates the chip areas with which contact is not to be made from the bonding wire.

The inventive step resides in the use of the standard aluminum wedge method for realizing buffer elements between chip front side and bonding wires. Bonding wire contacts can thus be realized independently of the chip geometry.

The use of a wedge buffer element makes it possible, by way of example, to increase the continuous-current carrying capacity of a TO252-3 housing for a chip having 2 mm² from presently 20 A (1*250 μm) to 95 A (2*500 μm) since, by means of the buffer element, even a 500 μm wire can be contact-connected on a small chip.

The invention is explained in more detail below on the basis of preferred embodiments with reference to a schematic drawing.

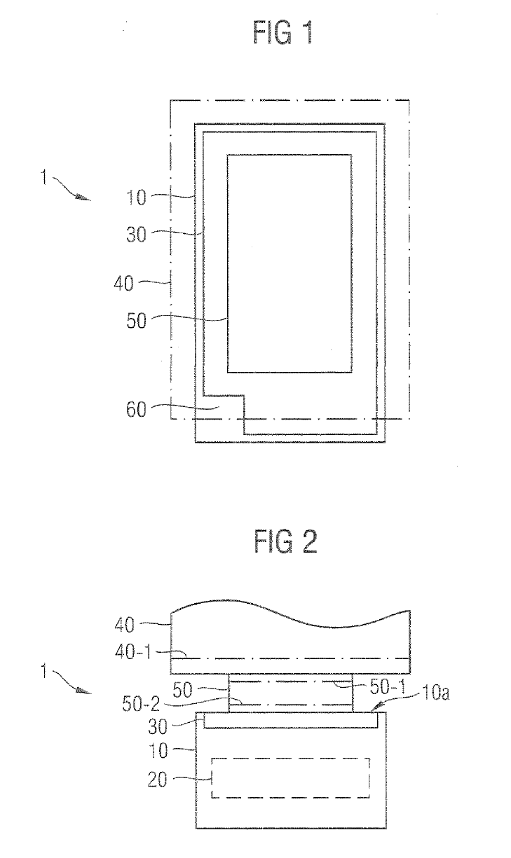

FIG. 1 is a plan view of a preferred embodiment of the semiconductor module according to the invention.

FIG. 2 is a lateral cross-sectional view of the embodiment of the semiconductor module according to the invention which is shown in FIG. 1.

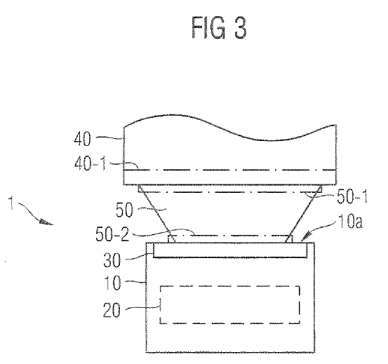

FIG. 3 is a lateral cross-sectional view of another embodiment of the semiconductor module according to the invention.

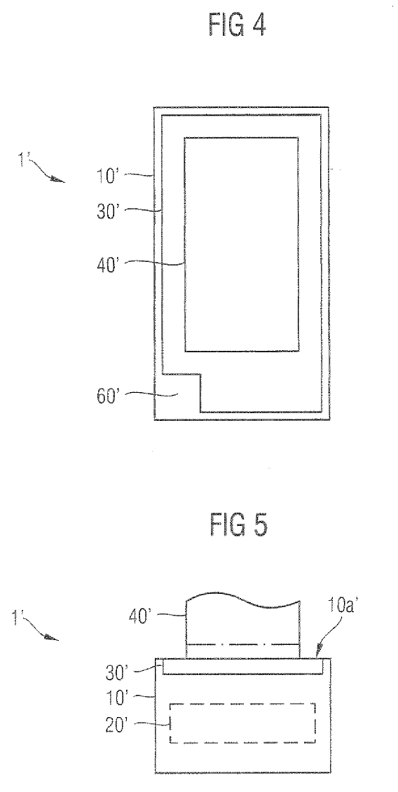

FIG. 4 is a plan view of a semiconductor module from the prior art.

FIG. 5 is a sectional side view of the embodiment from the prior art as shown in FIG. 4.

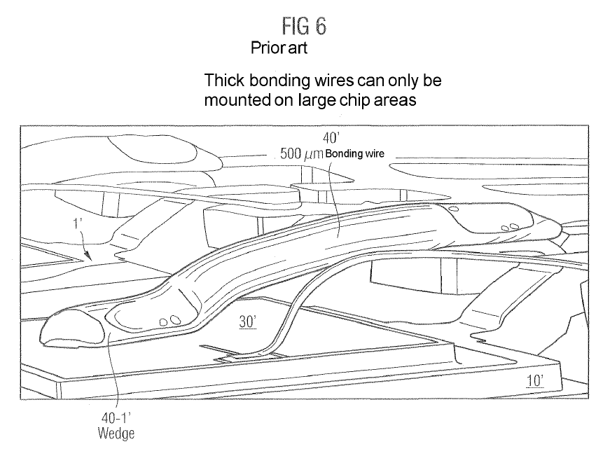

FIG. 6 is a photographic view of a contact-connection in the case of a semiconductor module from the prior art.

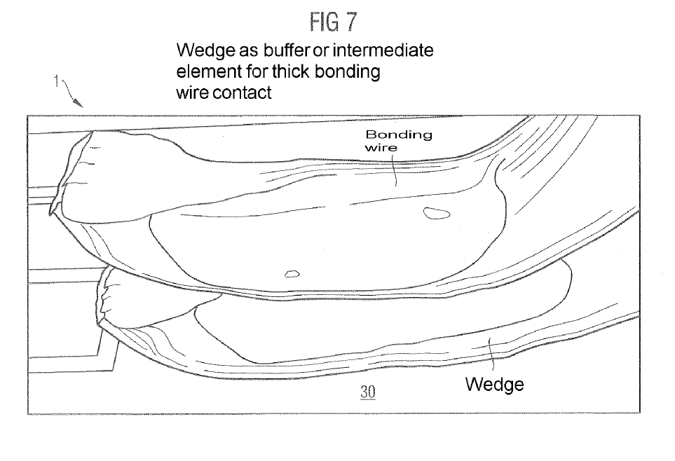

FIG. 7 is a photographic view of a contact-connection in the case of an embodiment of a semiconductor module according to the invention.

Structurally and/or functionally similar, comparable or equivalent elements are designated by the same reference symbols hereinafter. A detailed description of the respective elements is not repeated on every occasion when they occur.

FIG. 1 is a plan view of an embodiment of a semiconductor module 1 according to the invention, and FIG. 2 is a corresponding sectional side view.

The basis of this embodiment is a semiconductor region 10 or chip 10, which is illustrated as a rectangle in FIG. 1. The semiconductor region 10 or chip 10 has a top side 10a or a surface region 10a. By way of example, a power MOSFET with an edge structure is realized here by means of the embodiment of FIGS. 1 and 2. In this case, a contact region 30 or a pad 30 for a source region and also a contact region 60 or pad 60 for a gate region of a semiconductor element arrangement 20 realized in the module 1 are provided on the surface 10a or in the surface region 10a. An intermediate element 50 having a first end 50-1 and a second end 50-2 is also provided centrally in the contact region 30 or pad 30 for the source connection. The first end 50-1 of the intermediate element 50 is in material and electrical contact with the contact region 30 or pad 30 for the source connection. The opposite second end 50-2 is in contact with the first end 40-1 of the connection element 40, here in the form of a wedge buffer element, wedge bonding wire or the like, which is adjacent to the intermediate element 50. It emerges clearly from FIG. 1 that, on the one hand, the cross sections of the first and second ends 50-1 and 50-2, respectively, of the intermediate element 50 are formed approximately identically and, in particular, have an area which is less than the area of the contact region 30 or pad 30 for the source connection. The wedge bonding wire as connection element 40 that is adjacent to the second end 50-2 of the intermediate element 50 has, by contrast, in its end region 40-1, a cross-sectional area which is very much greater than the contact-making area made available by the contact region 30 or pad 30. It thus emerges from the arrangement of FIG. 1 that according to the invention, by virtue of the provision of the intermediate element 50, it is also possible to provide wires as connection elements 40 which have cross-sectional areas greater than the contact-making areas provided on the chip. Consequently, despite increasing miniaturization, it is possible to provide thicker connecting wires in conjunction with shrinking contact regions or pads 30.

FIG. 3 is a sectional side view of another embodiment of the semiconductor module 1 according to the invention.

The basis of this embodiment is likewise a semiconductor region 10 or chip 10. The semiconductor region 10 or chip 10 has a top side 10a or a surface region 10a. By way of example, a power MOSFET with an edge structure is likewise realized by means of the embodiment of FIG. 3.

A contact region 30 or a pad 30 for a source region and also a contact region 60 or pad 60 for a gate region of a semiconductor element arrangement 20 realized in the module 1 are provided on the surface 10a or in the surface region 10a. An intermediate element 50 having a first end 50-1 and a second end 50-2 is also provided centrally in the contact region 30 or pad 30 for the source connection.

The first end 50-1 of the intermediate element 50 is in material and electrical contact with the contact region 30 or pad 30 for the source connection. The opposite second end 50-2 is in contact with the first end 40-1 of the connection element 40, here in the form of a wedge buffer element, wedge bonding wire or the like, which is adjacent to the intermediate element 50.

It clearly emerges from FIG. 3 that, on the one hand, the cross sections of the first and second ends 50-1 and 50-2, respectively, of the intermediate element 50 are formed differently, the cross section of the first end 50-1 having an area which is less than the area of the contact region 30 or pad 30 for the source connection. The other or second end 50-2 of the intermediate element has a cross section having an area which is greater than that of the cross section of the first end 50-1. The intermediate element 50 therefore has e.g. the form of a truncated pyramid, and it is thus possible to bring about an improved adaptation of the cross-sectional areas.

The wedge bonding wire as connection element 40 that is adjacent to the second end 50-2 of the intermediate element 50 once again has, in its end region 40-1, a cross-sectional area which is very much greater than the contact-making area made available by the contact region 30 or pad 30. Consequently, it emerges from the arrangement of FIG. 3 that, according to the invention, by virtue of the provision of the intermediate element 50, it is also possible to provide wires as connection elements 40 which have cross-sectional areas greater than the contact-making areas provided on the chip. Consequently, despite rising miniaturization, it is possible to provide thicker connecting wires in conjunction with shrinking contact regions or pads 30.

The embodiment from the prior art which is illustrated in FIGS. 4 and 5 corresponds structurally essentially to the embodiment of the invention in accordance with FIGS. 1 and 2, but no intermediate element 40 is formed. The semiconductor region 10′ or chip 10′ provided here likewise has a surface region 10a′, on which contact-making regions or pads 30′, 60′ for a source region and for a gate region, respectively, of a power MOSFET 1′ are correspondingly formed and provided. The connection element 40′, here in the form of a 250 μm thick wire, is directly adjacent to the contact-making region or to the pad 30, so that the cross-sectional area of the first end 40-1′, which is directly materially and electrically connected to the contact-making region or pad 30′, directly matches the area contained in the contact-making region 30′ or pad 30′. Cross-sectional areas going beyond that, that is to say larger cross-sectional areas, for the connection element 40′ from the prior art are not possible, by contrast, so that an upper limit for the very large scale integration density arises solely on the basis of the contact-making necessity.

Semiconductor modules 1 in the form of power MOSFETs have been considered here by way of example. It goes without saying, however, that very much more complex semiconductor element arrangements 20 can also be realized by means of the semiconductor modules 1, a multiplicity of pads with corresponding assigned intermediate elements and connection elements also being conceivable.

FIG. 6 is a photographic view of a contact-connection in the case of a semiconductor module 1′ from the prior art, in which a thick bonding wire, in particular having a cross section of 500 μm, is provided as connection element 40′ on a large chip area as contact region 30′.

FIG. 7 is a photographic view of a contact-connection in the case of an embodiment of a semiconductor module 1 according to the invention, in which part of a thin bonding wire, in particular having a cross section of 250 μm, is provided as intermediate element 50 between a contact region 30 having a smaller extent and a thick bonding wire, in particular having a cross section of 500 μm, as connection element 40.

1.-10. (canceled)

11. An integrated circuit having a semiconductor module, comprising:
a semiconductor region having a semiconductor element arrangement and including a surface region;
a contact region formed on the surface region, configured to make electrical contact with the semiconductor element arrangement;
a connection element in electrical contact with the contact region; and
an intermediate element configured to make electrical contact between the contact region and the connection element.

12. The circuit of claim 11, comprising:
where the intermediate element is configured to materially and electrically directly connect the contact region to the connection element, for area adaptation between the contact region and the connection element.

13. The circuit of claim 11, comprising:
where the intermediate element is a wedge buffer element.

14. The circuit of claim 11, comprising:
where the contact region is formed on a front side of the semiconductor module.

15. The circuit of claim 11, comprising:
where the connection element is formed on a front side of the semiconductor module.

16. The circuit of claim 11, comprising:
where the connection element is formed as a bonding wire.

17. The circuit of claim 16, where the bonding wire is a wedge bonding wire.

18. The circuit of claim 11, comprising:
the intermediate element having a first end in material contact with the contact region, formed with a cross-sectional area less than or equal to a cross-sectional area of the contact region.

19. The circuit of claim 11, comprising:
the connection element having a cross section area greater than an area of the contact region.

20. The circuit of claim 11, comprising:
the intermediate element having first end and a second end, the second end in material and electrical contact with the connection element, formed with a cross section having an area greater than an area of the cross section of the first end, such that the area of the contact region is adapted to the area of the cross section of a first end of the connection element.

21. The circuit of claim 11, comprising:
where the contact region is a contact pad.

22. An integrated circuit having a semiconductor module, comprising:
a semiconductor region having a semiconductor element arrangement and including a surface region;
a contact region formed on the surface region, configured to make electrical contact with the semiconductor element arrangement;
a connection element in electrical contact with the contact region; and
means for providing an intermediate element configured to make electrical contact between the contact region and the connection element.

23. A semiconductor module comprising:
a semiconductor region having a semiconductor element arrangement and having a surface region;
at least one contact region formed on the surface region of the semiconductor region, in external electrical contact with the semiconductor element arrangement;
a connection element having a first end, which is formed in electrical contact with the contact region; and
an intermediate element, formed in electrical contact materially between the contact region and the connection element and in direct material and electrical contact with and for area adaptation between the connection element and the contact region.

24. The module of claim 23, comprising:
where the intermediate element is a wedge buffer element;
where the connection element is a bonding wire or as a wedge bonding wire;
the intermediate element having a first end, the first end in material contact with the contact region, formed with a cross section with which contact is to be made whose area is less than or equal to the cross-sectional area of the contact region with which contact is to be made; and
the connection element and the first end thereof being formed with a cross section whose area is greater than the area of the contact region.

25. The module of claim 24, comprising wherein the at least one contact region is formed at a front side of the semiconductor module.

26. The module of claim 25, comprising:
a plurality of contact regions are provided; and
each contact region is electrically connected to a respectively assigned connection element in each case via assigned intermediate elements.

27. The module of claim 25, comprising wherein the connection element is formed from one or more materials from a group consisting of aluminum, copper and gold.

28. The module of claim 25, comprising wherein the intermediate element having a second end, the second end being in material and electrical contact with the connection region, formed with a cross section having an area which is greater than the area of the cross section of the first end of the intermediate element such that the area of the contact region is thereby adapted to the area of the cross section of the first end of the connection element.

29. A method for producing a semiconductor module, comprising:
forming a semiconductor region having a semiconductor element arrangement and having a surface region;
providing at least one contact region formed on the surface region of the semiconductor region for externally making electrical contact with the semiconductor element arrangement;
forming a connection element having a first end in electrical contact with the contact region; and
forming an intermediate element for making electrical contact materially between the contact region and the connection element and in direct material and electrical contact with and for area adaptation between these.

30. The method of claim 29, comprising:
forming the intermediate element as a wedge buffer element;
forming the connection element in each case as a bonding wire;
the intermediate element having a first end, the first end being in material contact with the contact region, being formed with a cross section with which contact is to be made whose area is less than or equal to the cross-sectional area of the contact region with which contact is to be made; and
forming the connection element and the first end thereof with a cross section whose area is greater than the area of the contact region.

31. The method of claim 30, comprising forming the at least one contact region at a front side of the semiconductor module.

32. The method of claim 30, comprising providing a plurality of contact regions, and each contact region is electrically connected to a respectively assigned connection element in each case via assigned intermediate elements.

33. The method of claim 30, comprising forming the connection element in each case from or with one or more materials from the group consisting of aluminum, copper and gold.

34. The method of claim 30, comprising the intermediate element having a second end, the second end being in material and electrical contact with the connection region, is formed with a cross section having an area which is greater than the area of the cross section of the first end of the intermediate element such that the area of the contact region is thereby adapted in each case to the area of the cross section of the first end of the connection element.
